(19) United States
(12) Patent Application Publication
(10) Pub. No.: US 2005/0035891 A1
(43) Pub. Date: Feb. 17, 2005

(54) Digital-to-analog converter with level control

(75) Inventors: Mohammad Pirjaberi, San Jose, CA (US); Adya Tripathi, San Jose, CA (US)

Correspondence Address: BEYER WEAVER & THOMAS LLP, P.O. BOX 778, BERKELEY, CA, 94704-0778, US

(73) Assignee: Tripath Technology, Inc.

(21) Appl. No.: 10/900,500

(22) Filed: Jul. 28, 2004

Related U.S. Application Data
(60) Provisional application No. 60/495,747, filed on Aug. 14, 2003.

(51) Int. Cl. H03M 1/66

(52) U.S. Cl. 341/150

(57) ABSTRACT

Methods and apparatus are described for converting a digital data stream to an analog signal. Charge is added to and subtracted from an input of an integrator in a manner representative of the digital data stream thereby generating the analog signal at an output of the integrator. The amount of charge is varied thereby controlling the output level of the analog signal.

### RELATED APPLICATION DATA

The present application claims priority under 35 U.S.C. 119(e) to U.S. Provisional Patent Application No. 60/495,747 for ANALOG VOLUME CONTROL filed on Aug. 14, 2003 (Attorney Docket No. TRIPP041P) the entire disclosure of which is incorporated herein by reference for all purposes.

### BACKGROUND OF THE INVENTION

The present invention relates to techniques for converting digital data to an analog signal and controlling the level thereof. According to specific embodiments, such techniques are employed to provide volume control for digital audio amplifiers.

Digital-to-analog conversion may be accomplished using a Wagner switched capacitor DAC architecture. According to this technique, a fixed amount of charge is either added or subtracted at the input of an integrator in response to the state of the bits of a stream of digital data, i.e., the fixed amount of charge is added when a bit represents a “1” and subtracted when a bit represents a “0.” If the bit rate is sufficiently higher than the frequency range of interest, the charge accumulated by the integrator will result in an analog output signal representative of the digital data.

A variety of techniques have been conventionally employed to control the level of such an analog signal. For example, U.S. Pat. Nos. 6,127,893 and 6,693,491 (both of which are incorporated herein by reference for all purposes) both describe techniques for controlling the level of an audio signal in which the analog version of the signal is introduced into some variation of an R-2R network. These techniques are extremely effective, but consume valuable die area.

In addition, where the analog level being controlled has been derived from digital data, the range of volume control achieved in the analog domain may result in correspondingly deleterious effects on the fidelity of the analog signal generated. For example, in audio applications volume attenuation in the analog domain requires that the resolution of the digital data must be correspondingly increased to retain the same sound quality. For a typical 24 dB range of volume control, the resolution of the digital data would require four additional bits of resolution to offset the effects of attenuation in the analog domain. The impact of these four additional bits on the area consumed by the digital circuitry as well as the computational overhead associated with operation of the circuitry is significant.

It is therefore desirable to provide alternative techniques for controlling the level of an analog signal.

### SUMMARY OF THE INVENTION

According to the present invention, various methods and apparatus are provided for controlling the level of an analog signal. According to a first embodiment, a method for converting a digital data stream to an analog signal is provided. Charge is added to and subtracted from an input of an integrator in a manner representative of the digital data stream thereby generating the analog signal at an output of the integrator. The amount of charge corresponds to an output level of the analog signal. The amount of charge is varied thereby controlling the output level of the analog signal.

According to another embodiment, a digital-to-analog converter (DAC) is provided which includes an integrator and at least one switched capacitor circuit. The at least one switched capacitor circuit is operable to add and subtract an amount of charge to an input of the integrator in a manner representative of a digital data stream. The switched capacitor circuit is further operable to alternately employ each of a plurality of different capacitance values to accumulate the amount of charge. Each of the different capacitance values results in a different value for the amount of charge, and therefore a different output level of the integrator.

According to yet another embodiment, a DAC is provided which includes an integrator and a switched capacitor circuit. The switched capacitor circuit is operable to add and subtract an amount of charge to the integrator in a manner representative of a digital data stream. The switched capacitor circuit is further operable to alternately employ one of a plurality of different reference voltages to accumulate the amount of charge. Each of the plurality of reference voltages results in a different value for the amount of charge, and therefore a different output level of the integrator.

According to still another embodiment, a DAC is provided which includes an integrator and a switched capacitor circuit. The switched capacitor circuit is operable to add and subtract an amount of charge to the integrator in a manner representative of a digital data stream. The switched capacitor circuit is further operable to alternately employ one of a plurality of clock signals having different frequencies to accumulate the amount of charge. Each of the plurality of clock signals results in a different value for the amount of charge, and therefore a different output level of the integrator.

A further understanding of the nature and advantages of the present invention may be realized by reference to the remaining portions of the specification and the drawings.

### BRIEF DESCRIPTION OF THE DRAWINGS

FIG. 1 is a simplified schematic of a specific embodiment of the invention.

FIG. 2 is a simplified schematic of a second specific embodiment of the invention.

FIG. 3 is a simplified schematic of a third specific embodiment of the invention.

FIG. 4 is a simplified schematic of a fourth specific embodiment of the invention.

FIG. 5 is a simplified block diagram of a specific application of a particular embodiment of the invention.

### DETAILED DESCRIPTION OF SPECIFIC EMBODIMENTS

Reference will now be made in detail to specific embodiments of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims. In the following description, specific details are set forth in order to provide a thorough understanding of the present invention. The present invention may be practiced without some or all of these specific details. In addition, well known features may not have been described in detail to avoid unnecessarily obscuring the invention.

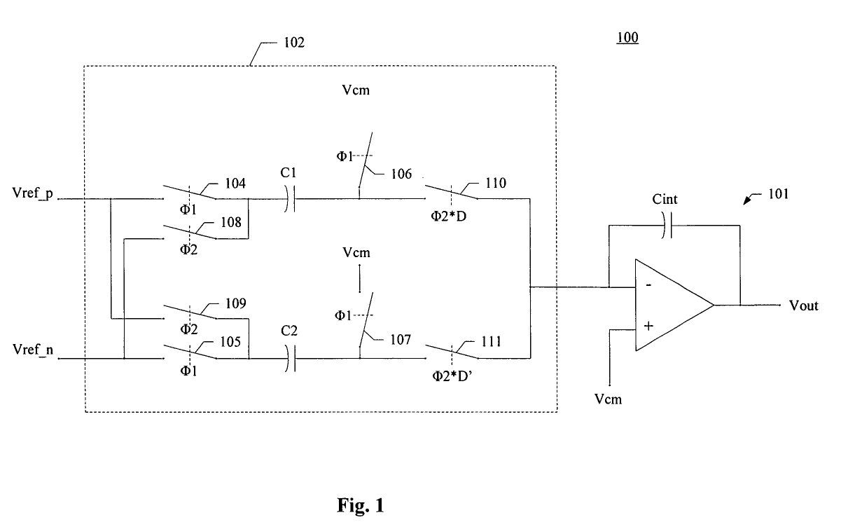

FIG. 1 is a simplified representation of a switched capacitor digital-to-analog converter (DAC) 100 which may be employed with various embodiments of the present invention. DAC 100 may be employed to convert 1-bit digital data, e.g., from a sigma-delta modulator or a pulse width modulator, to an analog signal by either adding or subtracting an amount of charge to or from the input of integrator 101 via the circuitry of module 102. By adding the amount of charge for each high and subtracting it for each low, the average voltage at the output of the integrator, i.e., Vout, will be an analog representation of the digital data stream.

Charge from fixed positive and negative voltage references Vref_p and Vref_n is stored in capacitors C1 and C2 (which have the same value) during the first half of a clock cycle, i.e., Φ1, through the action of switches 104-107 which connect C1 between Vref_p and the common mode voltage Vcm, and C2 between Vref_n and Vcm. During the second half of the clock cycle, i.e., Φ2, the charge from one of the capacitors is added or subtracted at the inverting input of integrator 101 through the action of switches 108 and 109 and one of switches 110 and 111 depending on whether the 1-bit data (represented by complementary signals D and D′) are high or low. The alternating nature of switches 110 and 111 is represented in the figure by the logical AND'ing of D and D′ with Φ2.

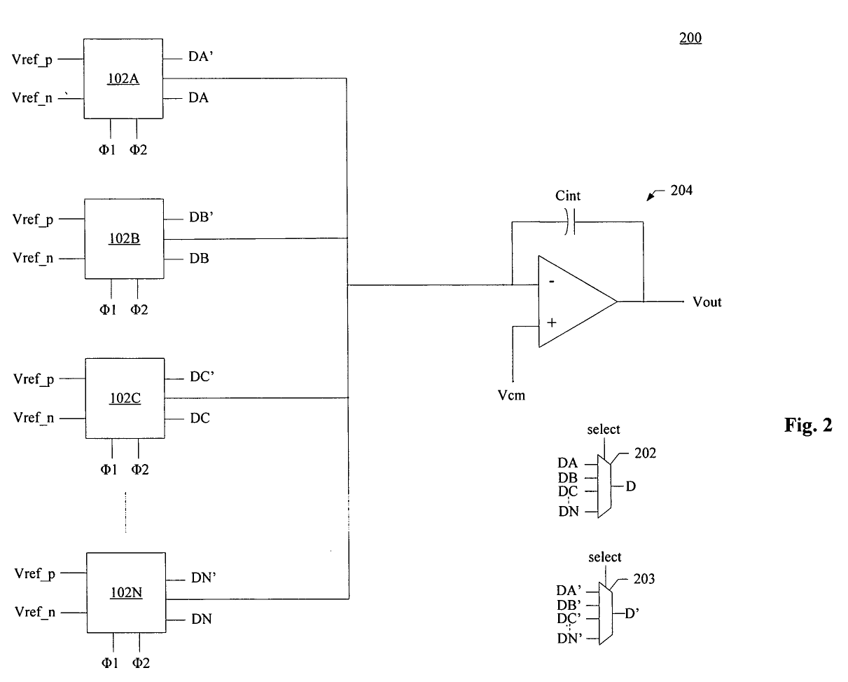

The quantum of charge being added or subtracted at the inverting input of integrator 101 (and thus the level of the output signal) is proportional to the capacitance value of C1 and C2. Therefore, according to a specific embodiment of the invention shown in FIG. 2, a DAC 200 is provided which includes multiple instances of module 102 of FIG. 1, each of which includes a pair of capacitors (i.e., C1 and C2) having a capacitance value which results in a particular output level. That is, for example, the capacitors in module 102A might be 1 pF while the capacitors of modules 102B and 102C might be 2 and 4 pF, respectively. Thus, the output levels corresponding to modules 102B and 102C would be, respectively, twice and four times the output level corresponding to module 102A.

As represented by the gating of data signals D and D′ via multiplexers 202 and 203, only one of modules 102 is enabled at a given time to add or subtract charge to integrator 204 depending on the desired output level. It will be understood that this representation is merely exemplary, and that the mechanism by which the selected module is enabled may vary considerably. As indicated, an arbitrary number of modules 102 may be included. Also, the relative sizes of the various pairs of capacitors in the various modules 102 may vary according to the desired precision of output level control.

It should be noted that the present invention is not limited by the embodiment shown and described above with reference to FIG. 2. That is, for example, another variable capacitance embodiment might be implemented with a single switched capacitor circuit in which the value of the capacitors is varied, e.g., by adding or subtracting capacitors in parallel for various desired output levels.

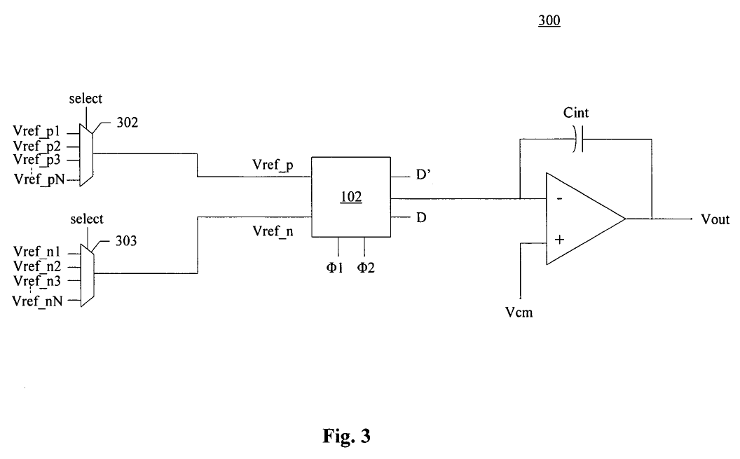

The quantum of charge being added or subtracted at the inverting input of integrator 101 of FIG. 1 is also proportional to the absolute value of complementary reference voltages Vref_p and Vref_n. Therefore, according to a specific embodiment of the invention shown in FIG. 3, a DAC 300 is provided in which module 102 alternately employs one of a plurality of pairs of reference voltages having different values to effect a desired output level. Selection of the particular reference voltages is illustrated using demultiplexers 302 and 303 for exemplary purposes. According to one embodiment, 6 dB steps are achieved by increasing the absolute value of Vref by two for each successive value. It should be noted that this implementation as well as the number of pairs of voltage references and the corresponding voltage levels may vary considerably and still remain within the scope of the invention.

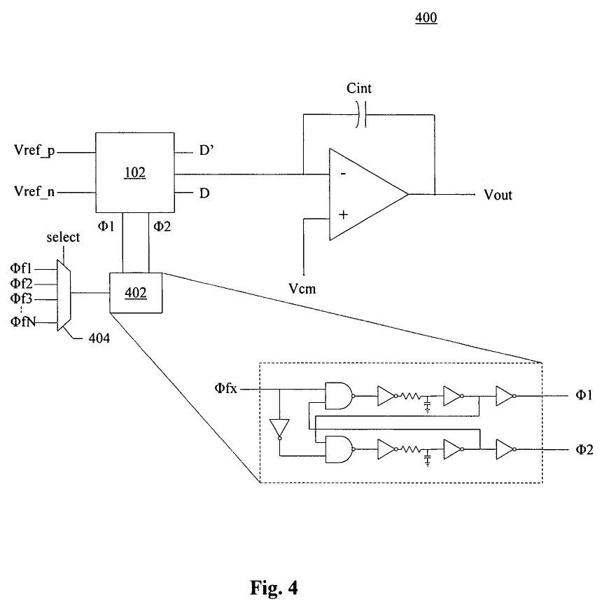

The quantum of charge being added or subtracted at the inverting input of integrator 101 of FIG. 1 is also proportional to the frequency of the clock Φ, the complementary versions of which (i.e., Φ1 and Φ2) are used to control the switches in module 102. That is, for example, if the clock rate were to be doubled, the total charge being added and subtracted from the integrator would correspondingly increase. Therefore, according to a specific embodiment of the invention shown in FIG. 4, a DAC 400 is provided in which the complementary representations of multiple clocks (i.e., Φf1-fN) are alternately provided to module 102 to effect a desired output level. The gating of the clocks to block 402 (which generates the complementary and non-overlapping versions of the clock) is illustrated by demultiplexer 404 for exemplary purposes. An exemplary circuit suitable for block 402 is shown. As with the previous embodiments, 6 dB steps may be achieved by having successive frequencies differ by a factor of two. It will be understood that this implementation as well as the number of clocks and the corresponding clock frequencies may vary considerably and still remain within the scope of the invention.

Because level control is achieved in the conversion from the digital domain to analog domain there is no need to provide additional bits of resolution in the digital domain to achieve some minimum standard of fidelity in the output signal. As will be understood, this results in a tremendous savings in die area as compared to implementations in which such additional bits and their attendant circuitry are required. Elimination of the need to provide separate level control circuitry results in further area savings.

While the invention has been particularly shown and described with reference to specific embodiments thereof, it will be understood by those skilled in the art that changes in the form and details of the disclosed embodiments may be made without departing from the spirit or scope of the invention. For example, embodiments of the invention are contemplated in which various combinations of the embodiments described above are employed. In one set of embodiments, both the capacitances and voltage references are varied to achieve level control. In another set of embodiments, both the voltage and clock frequencies are varied to achieve level control. In fact, any combination of these parameters may be varied and remain within the scope of the invention.

It should also be understood that embodiments of the present invention may be used in any of a wide variety of applications for which level control of the output of a digital-to-analog converter is desirable. One class of applications implements volume control for digital audio amplifiers. In particular, a digital amplifier design with which the present invention may be employed is described in U.S. Pat. No. 5,777,512, the entire disclosure of which is incorporated herein by reference for all purposes.

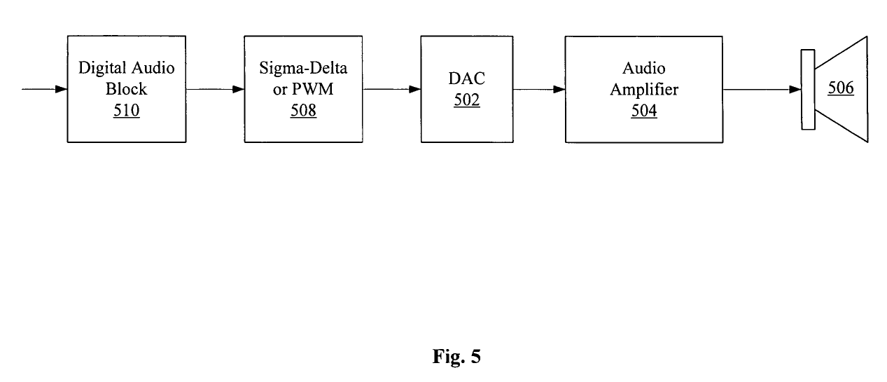

FIG. 5 is a simplified block diagram of an audio application in which the output of a DAC 502 designed according to a specific embodiment of the present invention is received by an audio amplifier 504 (which may be based, for example, on a sigma delta modulator, a modified sigma delta, or a pulse width modulator) which drives speaker 506. According to one embodiment, DAC 502 provides a coarse volume adjustment in 6 dB increments with finer adjustments (e.g., 1 dB increments) being provided within digital audio block 510. However, it will be understood that these intermediate increments may be provided in any of a wide variety of ways (e.g., both before and after DAC 502) without departing from the scope of the invention. In addition, modulation of the output of digital audio block 510 may be accomplished in a variety of ways as indicated by block 508 which, in different embodiments, may comprise a conventional or modified sigma-delta modulator, or even a pulse width modulator (PWM).

And as mentioned above, the technique of the present invention may be employed in a wide variety of applications beyond audio. This includes, for example, motor control applications, power factor correction, switching regulators, resonant mode switching, uninterrupted power supplies, etc; potentially thousands of applications. Therefore, although specific embodiments are described herein, it will be understood that the present invention may be optimized for use in many different applications.

In addition, although various advantages, aspects, and objects of the present invention have been discussed herein with reference to various embodiments, it will be understood that the scope of the invention should not be limited by reference to such advantages, aspects, and objects. Rather, the scope of the invention should be determined with reference to the appended claims.

1. A method for converting a digital data stream to an analog signal, comprising:
adding and subtracting an amount of charge to and from an input of an integrator in a manner representative of the digital data stream thereby generating the analog signal at an output of the integrator, the amount of charge corresponding to an output level of the analog signal; and
varying the amount of charge thereby controlling the output level of the analog signal.

2. The method of claim 1 wherein adding and subtracting the amount of charge to and from the input of the integrator is accomplished with at least one switched capacitor circuit.

3. The method of claim 2 wherein varying the amount of charge comprises varying a capacitance associated with the at least one switched capacitor circuit, the capacitance being for storing the amount of charge.

4. The method of claim 3 wherein the at least one switched capacitor circuit comprises a plurality of switched capacitor circuits, each switched capacitor circuit having a unique value of the capacitance associated therewith, only one of the switched capacitor circuits adding and subtracting the amount of charge at a time.

5. The method of claim 3 wherein varying the capacitance comprises selecting from among a plurality of capacitors.

6. The method of claim 2 wherein varying the amount of charge comprises varying a reference voltage associated with the at least one switched capacitor circuit, the reference voltage being for charging up a capacitance with the amount of charge.

7. The method of claim 6 wherein varying the reference voltage comprises selecting from a plurality of reference voltages.

8. The method of claim 2 wherein operation of the switched capacitor circuit is controlled by a clock signal characterized by a frequency, and wherein varying the amount of charge comprises varying the frequency of the clock signal.

9. The method of claim 8 wherein varying the frequency comprises selecting from among a plurality of frequencies.

10. The method of claim 2 wherein varying the amount of charge comprises any combination of varying a capacitance associated with the at least one switched capacitor circuit, varying a reference voltage associated with the at least one switched capacitor circuit, and varying a frequency of a clock signal controlling operation of the at least one switched capacitor circuit.

11. A digital-to-analog converter (DAC) comprising an integrator and at least one switched capacitor circuit operable to add and subtract an amount of charge to an input of the integrator in a manner representative of a digital data stream, the switched capacitor circuit further being operable to alternately employ each of a plurality of different capacitance values to accumulate the amount of charge, each of the different capacitance values resulting in a different value for the amount of charge, and therefore a different output level of the integrator.

12. The DAC of claim 11 wherein the at least one switched capacitor circuit comprises a plurality of switched capacitor circuits each comprising at least one capacitor corresponding to one of the different capacitance values, only one of the switched capacitor circuits being operable to add and subtract the amount of charge at a time.

13. The DAC of claim 11 wherein the at least one switched capacitor circuit comprises one switched capacitor circuit having at least one variable capacitor which may be adjusted to the different capacitance values.

14. The DAC of claim 11 wherein the at least one switched capacitor circuit is further operable to vary a reference voltage associated with the at least one switched capacitor circuit to further vary the output level of the integrator.

15. The DAC of claim 11 wherein the at least one switched capacitor circuit is further operable to vary a frequency of a clock signal controlling operation of the at least one switched capacitor circuit to further vary the output level of the integrator.

16. An audio amplifier comprising the DAC of claim 11 wherein an output volume of the audio amplifier corresponds to the output level of the integrator.

17. A digital-to-analog converter (DAC) comprising an integrator and a switched capacitor circuit operable to add and subtract an amount of charge to the integrator in a manner representative of a digital data stream, the switched capacitor circuit further being operable to alternately employ one of a plurality of different reference voltages to accumulate the amount of charge, each of the plurality of reference voltages resulting in a different value for the amount of charge, and therefore a different output level of the integrator.

18. The DAC of claim 17 wherein the switched capacitor circuit is further operable to vary a capacitance associated with the switched capacitor circuit to further vary the output level of the integrator.

19. The DAC of claim 17 wherein the switched capacitor circuit is further operable to vary a frequency of a clock signal controlling operation of the switched capacitor circuit to further vary the output level of the integrator.

20. An audio amplifier comprising the DAC of claim 17 wherein an output volume of the audio amplifier corresponds to the output level of the integrator.

21. A digital-to-analog converter (DAC) comprising an integrator and a switched capacitor circuit operable to add and subtract an amount of charge to the integrator in a manner representative of a digital data stream, the switched capacitor circuit further being operable to alternately employ one of a plurality of clock signals having different frequencies to accumulate the amount of charge, each of the plurality of clock signals resulting in a different value for the amount of charge, and therefore a different output level of the integrator.

22. The DAC of claim 21 wherein the switched capacitor circuit is further operable to vary a capacitance associated with the switched capacitor circuit to further vary the output level of the integrator.

23. The DAC of claim 21 wherein the switched capacitor circuit is further operable to vary a reference voltage associated with the switched capacitor circuit to further vary the output level of the integrator.

24. An audio amplifier comprising the DAC of claim 21 wherein an output volume of the audio amplifier corresponds to the output level of the integrator.
